(19) United States
(12) Patent Application Publication
(10) Pub. No.: US 2009/0161318 A1
(43) Pub. Date: Jun. 25, 2009

(54) THERMAL MANAGEMENT SYSTEMS AND METHODS

(75) Inventor: Ellen I. Sanderson, Denville, NJ (US)

Correspondence Address: WEINGARTEN, SCHURGIN, GAGNEBIN & LEBOVICI LLP, TEN POST OFFICE SQUARE, BOSTON, MA, 02109, US

(73) Assignee: DIALOGIC CORPORATION, Montreal (CA)

(21) Appl. No.: 11/960,519

(22) Filed: Dec. 19, 2007

(51) Int. Cl. H05K 7/20

(52) U.S. Cl. 361/709; 361/720

(57) ABSTRACT

Thermal management systems and methods for electronics. A printed circuit board assembly may include a soldered-in heat sink in communication with inner layers of a printed circuit board for cooling. The heat sink may include a plurality of leads received by plated through-holes in the printed circuit board. The heat sink may include features to augment surface area, as well as features to increase turbulence in a supplied cooling medium for enhanced convection. The heat sink may also include a heat pipe to facilitate cooling. The number, placement and configuration of the heat sinks may be optimized for a particular application to make efficient use of available surface area on the printed circuit board.

### FIELD OF THE TECHNOLOGY

The present invention relates generally to the field of electronics and, more particularly, to printed circuit board assemblies including heat sinks for thermal management and methods for removing heat from such assemblies.

### BACKGROUND

Printed circuit boards are widely used in the field of electronics to provide mechanical support and electrical connection among electronic components. Printed circuit boards may involve a single layer, or may include multiple layers having alternating sheets of a metal, typically copper, and a dielectric substrate for additional functionality. A printed circuit board populated with electronic components may generally be referred to as a printed circuit board assembly. Traces and/or planes etched in the metal layers of the printed circuit board offer conductive pathways between mounted electronic components.

Various techniques for mounting electronic components to printed circuit boards are known. Some components may be surface-mounted to pads on outer layers of the printed circuit board. Alternatively, holes may be drilled in printed circuit boards to receive leads associated with electronic components for through-hole construction. The walls of these holes in multilayer printed circuit boards are typically plated with copper to electrically interconnect applicable conducting layer(s). Soldering is generally used in both surface-mount and through-hole construction to secure the electronic components. For example, a ball grid array (BGA) of solder balls may be implemented in surface-mounting electronic components. Soldering may be performed by hand, or by machine, such as through bulk wave soldering or reflow oven operations.

The electronic components generate heat during operation which can cause significant equipment damage or malfunction if not controlled. Conventional thermal management products available for printed circuit board assemblies focus on heat sinks for electronic components, in which the heat sinks are typically mounted directly to the electronic components. Component-mounted heat sinks generally increase the thermal mass of the electronic component to lower its temperature while facilitating heat dissipation by conduction, convection and radiation.

A significant portion of heat generated by the electronic components is transferred to planes of the printed circuit board. The manner in which the electronic components are mounted to the printed circuit board, and the construction of the electronic components, may impact the amount of heat transferred to the printed circuit board. The printed circuit board planes to which generated heat is transferred are typically on inner layers of the printed circuit board. Restricted paths for heat to transfer to outer surfaces and ultimately to a cooling medium pose a challenge for thermal management. Printed circuit boards continue to grow more densely populated in response to industry demand for electronic devices of smaller size and greater capability. Pushing the power envelope with respect to printed circuit board design imposes notable layout restrictions and compounds thermal management concerns.

### SUMMARY

Aspects relate generally to systems and methods for thermal management of electronics.

In accordance with one or more aspects, a printed circuit board assembly may comprise a first electronic substrate having a first surface, at least one electronic component mounted on the first surface of the first electronic substrate, and a heat sink mounted on the first surface of the first electronic substrate adjacent to the at least one electronic component.

In some aspects, the heat sink may comprise a material with a thermal conductivity of at least about 300 W/mK at 300 K. The heat sink may comprise copper, and may comprise a sheet metal. In at least some aspects, the assembly may further comprise a source of a cooling medium in fluid communication with the heat sink. The heat sink may comprise a feature configured to enhance turbulence in the cooling medium. For example, the feature may comprise at least one relief defined by a surface of the heat sink.

In some aspects, the heat sink may comprise a lead received by an aperture formed in the first electronic substrate, and the lead may be in contact with a ground plane of the first electronic substrate. In some aspects, the heat sink may comprise a plurality of leads, and the first electronic substrate may define a plurality of apertures each adapted to receive a lead. In at least one aspect, the assembly may further comprise a second heat sink mounted on the first surface of the first electronic substrate adjacent to the at least one electronic component. The assembly may further comprise a second electronic substrate in electrical communication with the first electronic substrate.

In at least some aspects, the heat sink may be spaced from the at least one electronic component. In some aspects, the assembly may further comprise a heat pipe constructed and arranged to convey heat from the heat sink away from the printed circuit board assembly. The heat sink may be pitched relative to the first surface of the first electronic substrate. In some aspects, the heat sink may be oriented substantially perpendicular relative to the first surface of the first electronic substrate. In some aspects, the heat sink may be constructed and arranged to increase an effective surface area of the heat sink. For example, the heat sink may comprise at least one fin or fold. In certain aspects, the heat sink may be positioned between two electronic components.

In accordance with one or more aspects, a method of facilitating thermal management may comprise positioning a heat sink on a surface of an electronic substrate adjacent to an electronic component mounted on the substrate, and establishing thermal communication between the heat sink and an inner plane of the electronic substrate.

In some aspects, the method may further comprise directing a cooling medium toward the heat sink. The method may further comprise conveying heat away from the heat sink with a heat pipe. In at least some aspects, the method may further comprise securing the heat sink to the electronic substrate so that the heat sink engages a ground plane of the electronic substrate.

In accordance with one or more aspects, a printed circuit board assembly may comprise an electronic substrate having a first surface and an inner plane, an electronic component mounted on the first surface of the electronic substrate, and a heat sink, mounted on the first surface of the electronic substrate adjacent to the electronic component, and in thermal communication with the inner plane of the electronic substrate.

In some aspects, the heat sink may comprise a lead received by a through-hole defined by the electronic substrate. The lead may be in thermal communication with the inner plane of the electronic substrate.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

Various aspects of at least one embodiment are discussed below with reference to the accompanying figures. In the figures, which are not intended to be drawn to scale, each identical or nearly identical component that is illustrated in various figures is represented by a like numeral. For purposes of clarity, not every component may be labeled in every drawing. The figures are provided for the purposes of illustration and explanation and are not intended as a definition of the limits of the invention. In the figures:

FIG. 1 is a perspective view of a printed circuit board assembly in accordance with one or more embodiments;

FIG. 2 is a perspective view of one example of a heat sink in accordance with one or more embodiments;

FIG. 3 is a cross-sectional view of a printed circuit board assembly in accordance with one or more embodiments;

FIG. 4 is a perspective view of one example of a heat sink in accordance with one or more embodiments;

FIG. 5A is a cross-sectional view of a printed circuit board assembly in accordance with one or more embodiments;

FIG. 5B is a top plan view of the heat sink of the printed circuit board assembly of FIG. 5A;

FIG. 6A is a cross-sectional view of a printed circuit board assembly in accordance with one or more embodiments;

FIG. 6B is a top plan view of the heat sink of the printed circuit board assembly of FIG. 6A;

FIG. 7 is a perspective view of a printed circuit board assembly including a heat pipe in accordance with one or more embodiments; and

FIG. 8 presents thermal simulation data referenced in an accompanying Example.

### DETAILED DESCRIPTION

One or more embodiments relates generally to systems and methods for thermal management of electronics. The systems and methods described herein may find applicability in a wide variety of industries including, for example, the information technology, telecommunication, consumer goods, medical device, security, entertainment, display, imaging, and automotive sectors, as well as others in which there may be a demand for enhanced control of the thermal burden associated with implemented electronic devices. The systems and methods may provide a substantial advantage to designers and manufacturers of printed circuit board assemblies in managing high heat areas generated by mounted electronic components while making efficient use of often limited available space on the surfaces of printed circuit boards. The systems and methods disclosed herein may allow smaller and/or more densely populated printed circuit boards to be produced. The systems and methods may also be generally effective in providing alternate pathways for heat to escape from inner plane layers of multilayer printed circuit boards. Thus, disclosed systems and methods may enable cooling of printed circuit boards themselves as well as of electronic components mounted thereon through strategic placement, construction and arrangement of heat sinks. Beneficially, the stiffness of printed circuit board assemblies in accordance with one or more disclosed embodiments may also be greater than that of conventional printed circuit board assemblies, offering enhanced durability.

It is to be appreciated that embodiments of the systems and methods discussed herein are not limited in application to the details of construction and the arrangement of components set forth in the following description or illustrated in the accompanying drawings. The systems and methods are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items.

Embodiments of disclosed systems may generally involve an electronic substrate on which one or more electronic components are mounted. The electronic component(s) may be mounted on a surface of the electronic substrate in any known manner. Any number, and any variety of electronic components may be mounted on the electronic substrate, and they may generally be selected based on a desired functionality for the electronic assembly. The orientation, layout or arrangement of the electronic components on a surface of the electronic substrate may vary widely, for example, depending on an intended application and/or space constraints. The electronic component(s) may typically be an active electronic component, such as a semiconductor device. In some embodiments, heat generated by such active components may be managed by cooling the components and/or by extracting heat transferred to the electronic substrate as discussed in greater detail below. Additional electronic components may be passive devices, for example, resistors, capacitors, diodes or inductors.

The electronic substrate may provide mechanical support to the electronic component(s). The electronic substrate may also provide electrical communication or connection among the electronic components. In at least one embodiment, electrical connections may be made on the electronic substrate by traces and/or planes that are etched. The traces may be etched on a surface of the electronic substrate. In some embodiments, the electronic substrate may be a printed circuit board. Some embodiments may include a single electronic substrate. Other embodiments may include two or more electronic substrates. Multiple electronic substrates may be in electrical communication with one another for enhanced system functionality.

In accordance with one or more embodiments, a printed circuit board may include a layer of metal, such as a thin layer of copper, upon which one or more electronic components may be mounted to form a printed circuit board assembly. Electrical connection among electronic components may be made through traces and/or planes that are etched in the metal. The thin layer of copper may be laminated to a dielectric material, such as a plastic sheet. In some embodiments, multilayer printed circuit boards may have several such layers that are bonded together using dielectric material, pressure and/or heat. The electronic components may be mounted to the electronic substrate or printed circuit board in any manner commonly known to those skilled in the art. As discussed above, in some embodiments one or more electronic components may generally be surface-mounted or through-hole mounted. A soldering technique may generally be used to secure electronic component(s) to an electronic substrate as discussed in greater detail below and commonly known in the art. In some embodiments, a disclosed system may include two or more printed circuit boards in electrical communication therebetween for enhanced functionality.

Embodiments may also be generally effective in managing heat generated by one or more mounted electronic components, such as during electronic operation. In some embodiments, disclosed systems may include one or more heat sinks to manage generated heat. The heat sink(s) may generally be any environment or object capable of absorbing and/or dissipating heat from another object. The heat sink(s) may be made of any material compatible with environmental conditions associated with an intended application, particularly but not limited to temperature. In general, the heat sink(s) should be made of a material with a thermal conductivity value conducive to heat absorption and/or dissipation. For example, in some embodiments, the heat sink(s) may be made of a material with a thermal conductivity of at least about 200 W/mK at 300 K. In at least one embodiment, the heat sink(s) may be made of a material with a thermal conductivity of at least about 300 W/mK at 300 K. In one currently preferred embodiment, the one or more heat sinks are made of a material with a thermal conductivity of at least about 350 W/mK at 300 K. In some embodiments, the heat sink(s) may be made of a material with a thermal conductivity of at least about 400 W/mK. In at least one embodiment, the heat sink(s) may be made of a material with a thermal conductivity of at least about 380 W/mK at 300 K, such as copper, but the invention is not so limited. In selecting a material for the heat sink(s), consideration may also be given to the ability of the material to withstand an intended method of securing the heat sink(s) in the printed circuit board assembly, such as a soldering technique. Other factors may also influence the choice of material for the heat sink(s).

In some embodiments, heat generated by one or more mounted electronic components may thermally burden a printed circuit board assembly. The temperature of various mounted components, the electronic substrate and/or the surrounding environment of the assembly may be elevated by operation of active electronic components. Thermal management may generally facilitate normal operation and prevent system malfunction and/or breakage. One or more heat sinks according to one or more embodiments may be effective in cooling the assembly environment, including active components, surrounding components, and the printed circuit board, especially inner layers thereof, as discussed herein.

In some embodiments, two or more heat sinks, or multiple heat sinks may be incorporated. The number, shape, size, construction, position, arrangement and/or configuration of the heat sink(s) may be highly design dependent and specific to an intended application. Such variables may generally depend upon the layout of the printed circuit board and electronic component(s) mounted thereon. For example, component spacing constraints and limited space on the circuit board may be a consideration. The disclosed assemblies including heat sink(s) may generally make efficient and/or strategic use of valuable horizontal surface area on a printed circuit board, such as a printed circuit board surface. Furthermore, heat sink(s) according to at least one embodiment may facilitate optimizing space on a printed circuit board to facilitate design of more compact printed circuit boards. For example, in some embodiments, the heat sink(s) may comprise a thin sheet of metal with reduced footprint relative to a surface of the printed circuit board on which it is mounted.

In accordance with one or more embodiments, one or more heat sinks may be efficient in cooling an area or zone of a printed circuit board assembly. For example, the heat sink(s) may cool a high heat area of the printed circuit board assembly, or an area in the vicinity of one or more critical electronic components. In some embodiments, heat sink(s) may be effective in cooling a printed circuit board itself, including inner layers thereof. In certain embodiments, heat sink(s) may be effective in cooling one or more electronic components mounted on a printed circuit board, including both active and passive components.

In accordance with one or more embodiments, one or more heat sinks may provide a pathway for heat to escape from inner layers of multilayer printed circuit boards. Without wishing to be bound by any particular theory, generated heat may be transferred to printed circuit board planes on inner layers of a printed circuit board. Paths for such heat to transfer to outer surfaces for dissipation may generally be restricted. Embodiments may facilitate extraction of such heat for dissipation and removal as discussed herein. In some embodiments, one or more heat sinks may generally extend from within the printed circuit board to facilitate heat dissipation from inner layers. In at least one embodiment, the heat sink(s) may also generally extend above a surface of a printed circuit board to facilitate dissipation. The heat sink(s) may also be mounted substantially flush with a surface of the printed circuit board.

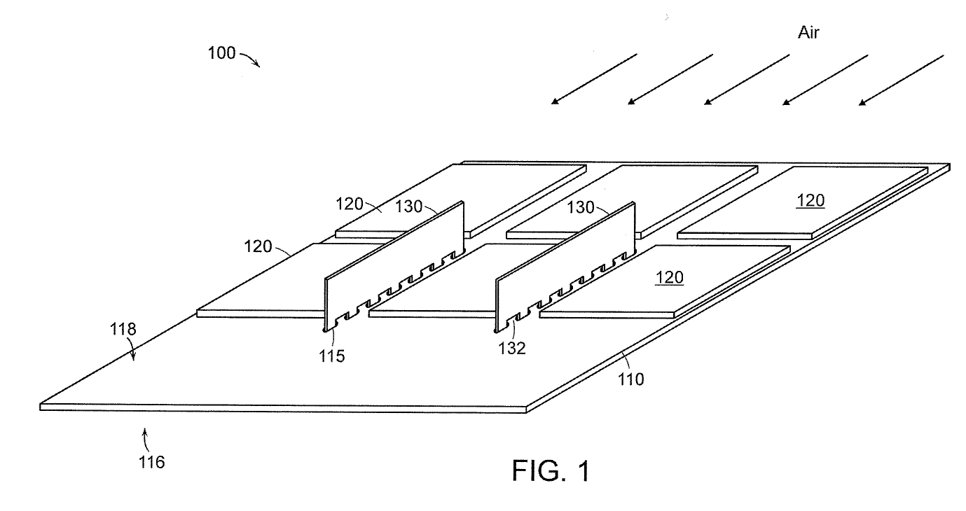

With reference to FIG. 1, a printed circuit board assembly 100 may generally include a printed circuit board 110 on which one or more electronic components 120 are mounted. The assembly 100 may also include one or more heat sinks 130. In some embodiments, heat sink(s) 130 may generally be positioned among the electronic component(s) 120 on a surface of the printed circuit board 110. In accordance with certain embodiments, heat sink(s) 130 may be positioned adjacent to the electronic component(s) 120 on the surface of the printed circuit board 110. For example, a heat sink 130 may be positioned next to one electronic component 120, or between two electronic components 120 on a surface of a printed circuit board 110. In some embodiments, heat sink(s) 130 may be positioned on the same side of printed circuit board 110 that electronic components 120 are mounted. In other embodiments (not shown), one or more heat sinks 130 may be positioned on a first side 116 of printed circuit board 110 which is opposite a second side 118 of printed circuit board 110 on which electronic components 120 are mounted. In still other embodiments (not shown), one or more heat sinks 130 may be positioned on first side 116 and one or more heat sinks 130 may also be positioned on second side 118. Strategic construction, placement and/or orientation of heat sink(s) 130 may generally facilitate cooling of electronic component(s) 120 as well as of the printed circuit board 110, including inner layers thereof.

A heat sink 130 may be positioned or spaced at any desired distance from an electronic component 120. Placement of a heat sink 130 relative to an electronic component 120 may depend on many considerations, such as the design of the printed circuit board 110 and/or the heat sink 130. For example, in some non-limiting embodiments, a space ranging from about 2 mm to about 15 mm may be provided between a heat sink 130 and a neighboring electronic component 120.

In accordance with one or more embodiments, heat sink(s) 130 may generally be in thermal communication with printed circuit board 110. Thermal communication may be established in a wide variety of ways in addition to those exemplarily discussed herein. In some embodiments, heat sink(s) 130 may be positioned on, mounted on and/or received by the printed circuit board 110. In this way, heat sink(s) 130 may generally be in communication or contact with one or more inner layers of the printed circuit board 110 to facilitate thermal management. In some embodiments, heat sink(s) 130 may generally promote extraction of heat from within the printed circuit board 110 for dissipation. Heat sink(s) 130 may also be efficient in cooling mounted components in the assembly environment.

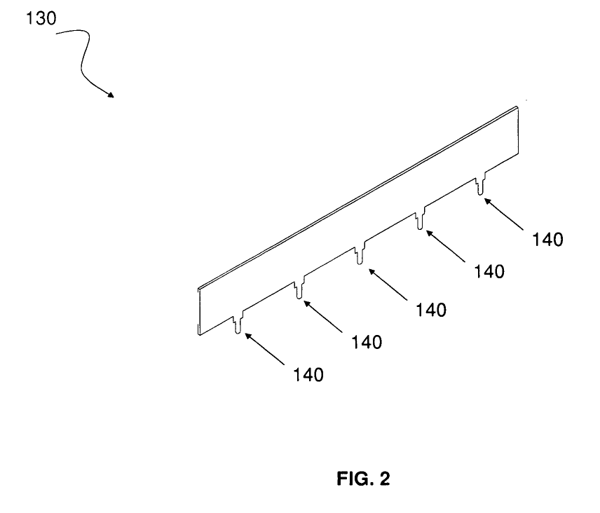

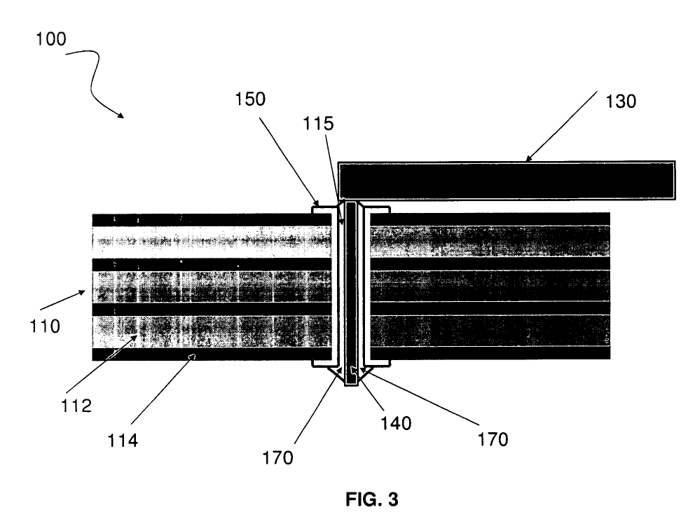

With reference to FIG. 3, the printed circuit board 110 may generally define one or more apertures, vias or through-holes 115. In some embodiments, through-holes 115 may extend throughout a thickness of the printed circuit board 110, or a portion thereof. In some embodiments, through-holes 115 may be generally configured to receive heat sink(s) 130. For example, as detailed in FIG. 2, heat sink 130 may include one or more leads, solder leads or solder pins 140 which may be received within the through-holes 115 of the printed circuit board 110. In at least one embodiment, through-holes 115 may be plated, such as with a metal, to form plated through-holes. The plating may contact one or more desired conducting layers within the printed circuit board 110 to create a conductive pathway, as discussed in greater detail below. Solder 170, which may be deposited during assembly, may secure the heat sink leads 140 within plated through-holes 115 to generally establish electrical and/or thermal communication. In some embodiments, molten solder 170 may flow into plated through-holes around lead 140 during assembly, securing the lead 140 upon hardening to thermally connect its associated heat sink 130 to one or more inner layers of printed circuit board 110 for cooling. In some embodiments, more than one heat sink 130 may be present, and one, some or all heat sink(s) 130 may have one or more associated leads 140.

In accordance with one or more embodiments, heat sink leads 140 may provide thermal communication between their associated heat sink(s) 130 and one or more inner layers 112 and/or outer layers of printed circuit board 110. In some embodiments, it may therefore be beneficial to implement a plurality of leads 140, such as a predetermined number that will allow for maximization of heat transfer from inner layers 112 of the printed circuit board 110 for dissipation and extraction. Space and layout constraints of the printed circuit board 110, such as may be due to electronic components mounted thereon, may impact the number and/or placement of leads 140 associated with a heat sink 130.

In some embodiments, leads 140 may comprise solder pins. In at least one embodiment, the lead(s) 140 may be integral to its associated heat sink 130. Leads 140 may have a similar, smaller or larger size form factor to that of a conventional leaded-through mounted electronic component. Likewise, through-holes 115 may have a similar, smaller or larger size form factor to that of conventional through-holes for lead-through mounting of components.

The leads 140 may generally be in thermal communication with one or more inner layers 112 of printed circuit board 110. Such thermal communication may be established in a variety of ways in addition to those exemplarily discussed herein. For example, and as discussed above, the leads 140 may be secured, such as soldered, to engage one or more inner layers 112 of the printed circuit board 110 within plated through-holes 115 and thus generally connect to or thermally communicate with printed circuit board inner planes for cooling. The quantity of solder pins may be maximized if possible, depending on surface space constraints, to promote heat extraction from inner planes 112 of the printed circuit board 110 and to increase structural stability of the heat sink 130.

Still referring to FIG. 3, there is illustrated in cross-section a portion of a multilayer printed circuit board assembly 100 including heat sink 130 and printed circuit board 110. As discussed above, a solder pin or lead 140 of heat sink 130 is inserted within through-hole 115, in accordance with at least one embodiment. The through-hole 115 extends through the multiple layers the printed circuit board 110, some or all of which have signal traces (not shown) disposed thereon. Solder 170 may be used to secure the heat sink 130, such as by soldering it to a ground plane 114 of the printed circuit board 110. In some embodiments, the heat sink lead or solder pin 140 may extend out from beyond an end of the through-hole 115 above one or both of the top and bottom surfaces of the printed circuit board 110.

According to one embodiment, solder may be deposited over the through-hole and/or through-hole pads (not shown) on a printed circuit board outer layer, such that it contacts the solderable terminals or leads of the heat sink, and standard assembly processes (such as those used to solder surface mount components to a printed circuit board) may be used to melt the solder and secure the heat sink, as discussed further below. Contact or connection, such as from outer layer pads (not shown) to one or more plane layers, should generally be made so as to facilitate heat transfer from the printed circuit board planes to the leads 140. As discussed above, through-holes 115 may be coated or plated with a conductive material 150, such as a metal. In some embodiments, the through-holes 115 may be coated in copper. In the case of multilayer printed circuit boards (see FIG. 3), the coating 150 may provide electrical communication between various layers of the printed circuit board. According to one embodiment, the through-hole 115 may be plated along a portion or all of the sides forming the through-hole. In some embodiments of operation, heat may dissipate from an inner layer 112 of the printed circuit board 110 to lead 140 of the heat sink 130 via coating 150 for extraction.

In accordance with one or more embodiments, thermal management may be facilitated by one or more assembly features. Heat sink(s) 130 may facilitate heat extraction from electronic substrates, including inner layers thereof, in addition to cooling surrounding components by heat transfer. In some embodiments, the disclosed printed circuit board assemblies 100 may be generally cooled by convection and/or, at least in part, by transport or conduction of heat away from one or more components of the assembly 100. For example, disclosed systems may include a source of a cooling medium in fluid communication with the printed circuit board assemblies 100. The cooling medium may generally be directed towards the assembly 100. In some embodiments, the source of a cooling medium may be a source of air such that the movement of the air facilitates cooling. In some embodiments, forced air may be used. Contact of various components of the printed circuit board assembly 100 with the cooling medium may promote heat dissipation and system cooling. For example, the cooling medium may be in contact with one or more heat sinks 130 of the assembly 100. The cooling medium may facilitate dissipation of heat collected by the heat sink(s) 130 from electronic assembly components and/or the printed circuit board 110 and inner layers thereof as discussed herein. The cooling medium may also contact one or more electronic components 120 of the assembly 100 for cooling.

In some embodiments, the orientation of the heat sink(s) 130 relative to the printed circuit board 110 and electronic component(s) 120 thereon may generally cooperate or compliment an overall cooling design for the assembly 100. More specifically, if a cooling medium is being used in conjunction with one or more heat sinks 130, then the heat sink(s) 130 may be oriented such that the cooling medium generally flows along their length to facilitate cooling. In some embodiments, the heat sink(s) 130 may be oriented at a pitch 132 (see FIG. 1) relative to a surface of the printed circuit board 110. Without wishing to be bound to any particular theory, varying the heat sink pitch 132 may beneficially impact heat transfer rates, such as a convection rate, within the system to facilitate cooling and thermal management. In some embodiments, the heat sink(s) 130 may be oriented substantially perpendicular with respect to a surface of the printed circuit board 110. In other embodiments, the heat sink(s) 130 may be oriented at any other angle relative to a surface of the printed circuit board 110. Effectiveness and/or space constraints may impact angle selection. Placement and orientation of electronic components 120 may also be strategically determined.

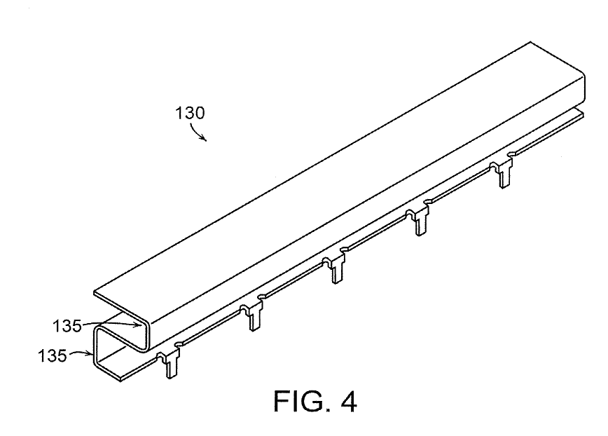

Furthermore, the heat sink(s) 130 may include one or more features to promote heat transfer between the heat sink(s) 130 and a supplied cooling medium. For example, in accordance with certain embodiments, the heat sink(s) 130 may include one or more surface features configured to increase an effective surface area of the heat sink(s) 130 to promote heat transfer with the cooling medium. Such surface features may include fins, folds, pleats, creases or other similar facet. FIG. 4, for example, illustrates folds 135 in the sheet metal of a heat sink 130 thereby increasing or augmenting an effective surface area of the heat sink 130. Such surface features may, in some embodiments, create channels in the heat sink(s) 130.

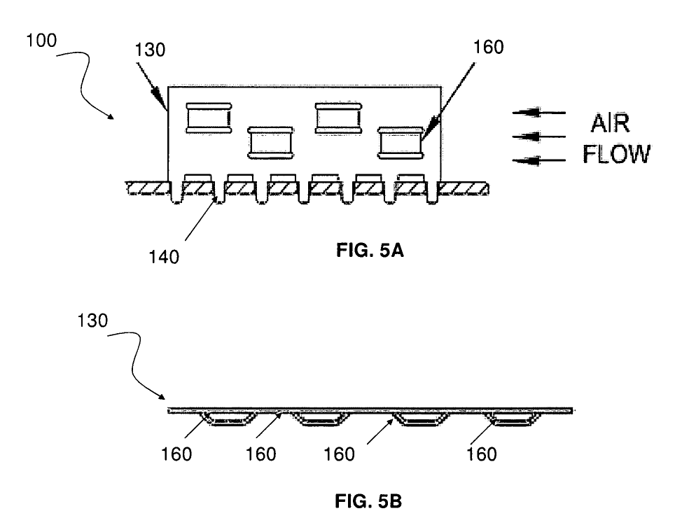

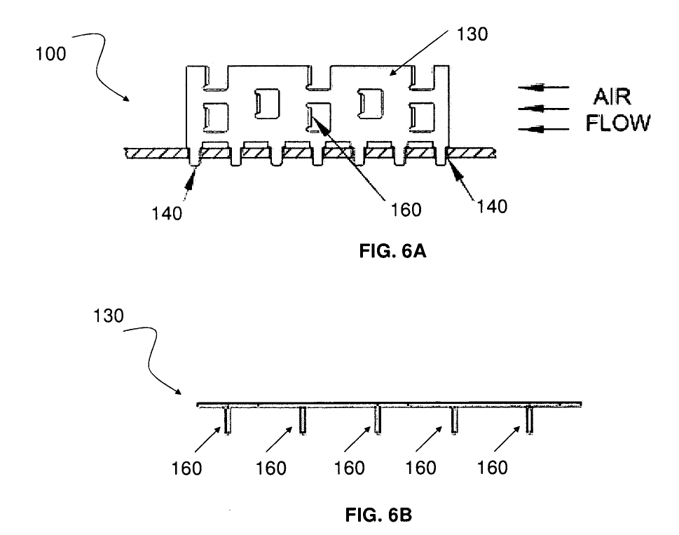

Likewise, the heat sink(s) 130 may include one or more surface features to increase turbulence in fluid flow around the heat sink(s), in turn increasing a rate of heat transfer at a surface of the heat sink(s). Such features, such as dimples, indentations, notches, grooves and bumps may stir air at the heat sink surface. FIGS. 5A and 6A, for example, illustrate sample non-limiting surface modifications 160 to cause turbulence thereby promoting heat transfer. FIGS. 5B and 6B provide top plan views of these surface treatments 160, respectively, for perspective.

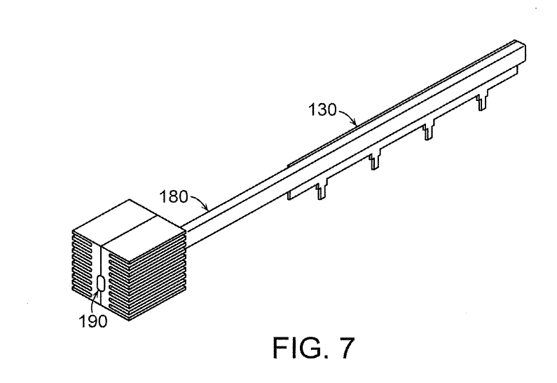

In accordance with various embodiments, the printed circuit board assembly 100 may also include one or more features adapted to facilitate extraction of heat away from the printed circuit board 110. In some embodiments, heat sink(s) 130 may include one or more such features. The feature(s) may include one or more heat transfer mechanisms capable of transferring heat from one point to another. For example, in some embodiments, one or more heat pipes may be provided to rapidly move heat to where it can be effectively removed by a system cooling medium. In some embodiments, one or more heat pipes or other heat transfer mechanisms may generally transfer heat by evaporation and condensation of an internal fluid. In at least one embodiment, one or more heat pipes or other heat transfer mechanisms may transport heat with a small temperature difference between hot and cold boundaries. FIG. 7 illustrates an elongated heat pipe 180 in accordance with one or more embodiments engaged with a heat sink 130. The heat pipe 180 is generally extending between the heat sink 130 and a cooling body 190 to promote heat dissipation.

The dimensions of the heat sink(s) 130 should generally be selected with attention to the thermal management requirements of the system, as well as space constraints associated with the layout of the printed circuit board assembly 100. Thus, each parameter is design specific and should be separately optimized for each intended application. The thickness of the heat sink(s) 130 should generally be conducive to properly securing the heat sink, such as through a soldering operation. The height of the heat sink(s) 130 should also be selected based on the requirements of the intended application. Without wishing to be bound by any particular theory, effectiveness of the heat sink(s) 130 may not increase with height beyond a certain point. This may depend on various characteristics of the heat sink(s) 130, for example, the thermal conductivity of the heat sink material to be used, and/or the thickness of the heat sink(s) 130.

In some embodiments, the heat sink(s) 130 may occupy very little horizontal space on the printed circuit board 110. For example, the heat sink(s) 130 may comprise a thin sheet, such as a thin sheet of metal. The thin sheet may generally extend from a surface of the printed circuit board 110. The thin sheet may be in thermal communication with inner layers 112 of the printed circuit board 110, such as through leads 140 in plated through-holes 115 as discussed above. In some embodiments, a thin sheet heat sink 130 may be between about 40 and 60 mm in length, 10 and 15 mm in height, and 0.2 to 0.5 mm in thickness. Such range of dimensions is not intended to be limiting. Instead, it may be used a starting point for design to meet requirements associated with a particular application. The size of the heat sink(s) 130 may be optimized by thermal analysis in accordance with one or more embodiments. Thus, strategic design and arrangement of one or more heat sinks 130 may save considerable component space on the printed circuit board 110 and facilitate the production of higher density printed circuit boards 110.

According to one embodiment, a method of producing a populated printed circuit board may include placing one or more heat sinks 130 on the printed circuit board 110 before or during the process of populating the board with other active and/or passive components 120. In some embodiments, the heat sink(s) 130 may be brought into thermal communication with one or more inner layers 112 of the printed circuit board 110 to facilitate heat extraction therefrom. The heat sink(s) 130 may be positioned relative to mounted electronic component(s) 120 to facilitate cooling of the assembly environment. Conventional surface mount components are generally fed into a component dispensing machine, known in the art as a pick-and-place machine. Similarly, in at least one embodiment, heat sink(s) 130 may be fed into a dispensing machine adapted to accommodate such components. Alternatively, heat sink(s) 130 may be placed manually, such as by hand. Conventional or similar fixtures may be used to hold the printed circuit boards 110 during placement of the heat sink(s) 130 as with other components.

After placement/insertion of the heat sink(s) 130 and other electronic component(s) 120 on the printed circuit board 110 is complete, the components may be secured in place, such as by soldering. In one example, a technique known in the art as wave soldering may be used to implement this step for the heat sink(s) 130 and other components using through-hole mounting techniques. Alternatively, a solder dispensing tool may be used to apply solder paste to the solderable lands and pads on one side of the printed circuit board 110. The printed circuit board 110 may then be placed in clamps on a conveyor belt. The conveyor belt may run past multiple stations where mechanical dispensers insert the heat sink(s) 130 and other applicable through-hole components and press any surface mount components onto the board 110. Next, the board 110 may be sent to a convection oven where the solder paste is melted, creating a solder joint. This procedure may then be repeated for the opposite side of the board 110 if necessary.

After the assembly process takes place, the printed circuit board 110 may be tested for any faults prior to packaging and shipment to a customer. According to one embodiment, if any component fails, for example, is cracked from the insertion force and/or exposure to high temperatures (e.g., during soldering), then a rework process may be implemented to replace the component. The disclosed heat sink(s) 130 and electronic component(s) 120 mounted on the printed circuit board 110 can be removable, such as through solder rework processes commonly known to those in the art. Existing printed circuit board assemblies may also be retrofitted in accordance with various embodiments discussed herein for thermal management.

Heat sink(s) 130 in accordance with one or more embodiments may be effective in providing alternative pathways for heat dissipation from inner layers of printed circuit boards 110. The heat sink(s) 130 may extract heat from inner layers 112 for cooling and may be generally effective in cooling areas of printed circuit board assemblies 100, including the printed circuit board 110 itself and surrounding electronic components 120. The heat sink(s) 130 in accordance with various embodiments may be used in conjunction with traditional component-mounted heat sinks, as well as with other thermal management components as part of an overall thermal management system.

The function and advantages of these and other embodiments will be more fully understood from the following example. This example is intended to be illustrative in nature and is not to be considered as limiting the scope of the systems and methods discussed herein.

### EXAMPLE

Thermal simulation was performed using Flotherm CFD software, commercially available from Flomerics Inc. of Marlborough, Mass., to determine the cooling effect(s) of a soldered-in printed circuit board heat sink(s). Twelve different scenarios were considered, each using the same printed circuit board, thermal duct environment, heat source (component), and heat sink design. The quantity of heat sinks and components were varied between runs. The configuration of the printed circuit board in each scenario was generally in accordance with that depicted in FIG. 1. The electronic components used were 35 mm by 35 mm PBGA type, each dissipating 5 Watts. The printed circuit board was a four-layer board which was 20% copper at its outer layers and 80% copper in its inner layers. The dimensions of the printed circuit board were 127 mm (length)×127 mm (width)×1.6 mm (thickness). Forced airflow at 40 degrees Celsius was provided at a velocity of 200 LFM. The heat sink was a solder-in copper heat sink which was 40.64 mm in length, 11.97 mm in height, and 0.38 mm in thickness. The heat sink included seven solder pins of 3.87 mm in length and 2.54 mm in width arranged at a pitch of 6.35 mm along the heat sink length. The heat sink was oriented at a 90 degree angle (perpendicular) to the printed circuit board.

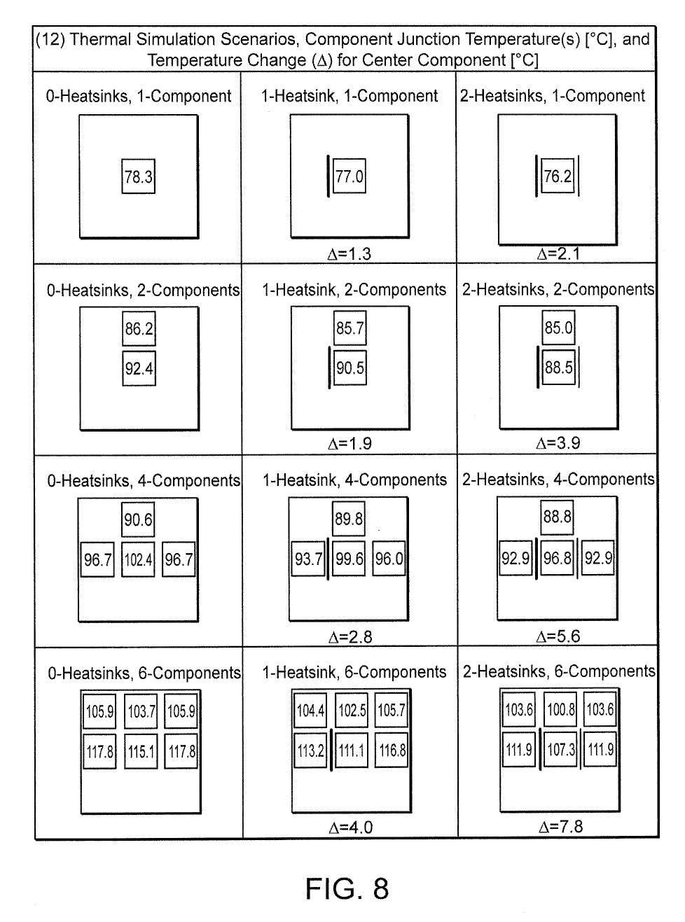

FIG. 8 shows a pictorial representation of each simulation including number of components, number/placement of heat sinks, and resulting component temperatures. The centermost component temperature is shown in italics and its temperature change (Δ) due to the presence of the solder-in heat sink(s) is noted. The temperature of all surrounding components was also reduced by the heat sink(s). The component temperatures presented are junction temperatures.

It was illustrated that a solder-in printed circuit board heat sink is an effective means to reduce component temperatures in densely populated, high heat areas on a printed circuit board assembly. The amount of temperature reduction achieved is highly design dependent, driven by heat sink physical design, number of heat sinks used, and printed circuit board assembly layout.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A printed circuit board assembly, comprising:
a first electronic substrate having a first surface;
at least one electronic component mounted on the first surface of the first electronic substrate; and
a heat sink mounted on the first surface of the first electronic substrate adjacent to the at least one electronic component.

2. The assembly of claim 1, wherein the heat sink comprises a material with a thermal conductivity of at least about 300 W/mK at 300 K.

3. The assembly of claim 2, wherein the heat sink comprises copper.

4. The assembly of claim 1, wherein the heat sink comprises a sheet metal.

5. The assembly of claim 1, further comprising a source of a cooling medium in fluid communication with the heat sink.

6. The assembly of claim 5, wherein the heat sink comprises a feature configured to enhance turbulence in the cooling medium.

7. The assembly of claim 6, wherein the feature comprises at least one relief defined by a surface of the heat sink.

8. The assembly of claim 1, wherein the heat sink comprises a lead received by an aperture formed in the first electronic substrate.

9. The assembly of claim 8, wherein the lead is in contact with a ground plane of the first electronic substrate.

10. The assembly of claim 1, wherein the heat sink comprises a plurality of leads, and wherein the first electronic substrate defines a plurality of apertures each adapted to receive a lead.

11. The assembly of claim 1, further comprising a second heat sink mounted on the first surface of the first electronic substrate adjacent to the at least one electronic component.

12. The assembly of claim 1, further comprising a second electronic substrate in electrical communication with the first electronic substrate.

13. The assembly of claim 1, wherein the heat sink is spaced from the at least one electronic component.

14. The assembly of claim 1, further comprising a heat pipe constructed and arranged to convey heat from the heat sink away from the printed circuit board assembly.

15. The assembly of claim 1, wherein the heat sink is pitched relative to the first surface of the first electronic substrate.

16. The assembly of claim 15, wherein the heat sink is oriented substantially perpendicular relative to the first surface of the first electronic substrate.

17. The assembly of claim 1, wherein the heat sink is constructed and arranged to increase an effective surface area of the heat sink.

18. The assembly of claim 17, wherein the heat sink comprises at least one fin or fold.

19. The assembly of claim 1, wherein the heat sink is positioned between two electronic components.

20. A method of facilitating thermal management, comprising:
positioning a heat sink on a surface of an electronic substrate adjacent to an electronic component mounted on the substrate; and
establishing thermal communication between the heat sink and an inner plane of the electronic substrate.

21. The method of claim 20, further comprising directing a cooling medium toward the heat sink.

22. The method of claim 21, further comprising conveying heat away from the heat sink with a heat pipe.

23. The method of claim 20, further comprising securing the heat sink to the electronic substrate so that the heat sink engages a ground plane of the electronic substrate.

24. A printed circuit board assembly, comprising:
an electronic substrate having a first surface and an inner plane;
an electronic component mounted on the first surface of the electronic substrate; and
a heat sink, mounted on the first surface of the electronic substrate adjacent to the electronic component, and in thermal communication with the inner plane of the electronic substrate.

25. The assembly of claim 24, wherein the heat sink comprises a lead received by a through-hole defined by the electronic substrate, and wherein the lead is in thermal communication with the inner plane of the electronic substrate.
